(19) United States
(12) Patent Application Publication
(10) Pub. No.: US 2007/0246719 A1
(43) Pub. Date: Oct. 25, 2007

(54) P-N Junction-Type Compound Semiconductor Light-Emitting Diode

(75) Inventors: Michiya Odawara, Saitama (JP); Takashi Udagawa, Saitama (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., MINATO-KU, TOKYO (JP)

(21) Appl. No.: 11/579,550

(22) PCT Filed: May 6, 2005
(86) PCT No.: PCT/JP05/08735

§ 371 Date: Feb. 20, 2007

Related U.S. Application Data
(60) Provisional application No. 60/572,268, filed on May 19, 2004.

(30) Foreign Application Priority Data
May 6, 2004 (JP) 2004-137229

(51) Int. Cl. H01L 33/00

(52) U.S. Cl. 257/94; 257/E33.001

(57) ABSTRACT

In a p-n junction-type compound semiconductor light-emitting diode provided on a crystal substrate with at least an n-type active layer formed of a Group m nitride semiconductor as a light emitting layer, and with a Group m nitride semiconductor layer containing a p-type impurity on the n-type active layer, the diode has a boron phosphide-based Group III-V compound semiconductor layer possessing a band gap exceeding that of the Group m nitride semiconductor forming the n-type active layer at room temperature and exhibiting a p-type electroconductivity in an undoped state deposited on the p-type impurity-containing Group III nitride semiconductor layer, and has an ohmic positive electrode joined to a surface of the boron phosphide-based Group III-V compound semiconductor layer.

### CROSS REFERENCE TO RELATED APPLICATIONS

This application is an application filed under 35 U.S.C. § 111 (a) claiming the benefit pursuant to 35 U.S.C. § 119 (e) (1) of the filing dates of Provisional Application No. 60/572,268 filed May 19, 2004 and Japanese Patent Application No. 2004-137229 filed May 6, 2004 pursuant to 35 U.S.C. § 111 (b).

### TECHNICAL FIELD

This invention relates to a p-n junction-type compound semiconductor light-emitting diode provided on a crystal substrate with at least an n-type active (light-emitting) layer formed of a Group III nitride semiconductor and with a Group III nitride semiconductor layer containing a p-type impurity on the n-type active layer.

### BACKGROUND ART

As light-emitting devices for mainly emitting blue through green light, the light-emitting diode (LED) and laser diode (LD) using as a Group III-V compound semiconductor (Group III nitride semiconductor) layer containing nitrogen (N), for example, as a Group V component element light-emitting layer have been known heretofore (refer, for example, to JP-A SHO 49-19783). In the LED which emits short-wavelength visible light, the light-emitting layer which is mainly formed of gallium indium nitride mixed crystal (Ga_{Y}In_{Z}N: 0≦Y, Z≦1, Y+Z=1) has been being used (refer, for example, to JP-B SHO 55-3834).

In the light-emitting layer formed of the gallium indium nitride mixed crystal (Ga_{Y}In_{Z}N), the light-emitting layer is usually joined to a clad layer to form a hetero junction for enhancement of the efficiency of radiation recombination and acquiring emission of high intensity (refer, for example, to “Group III-V Compound Semiconductors” written by Isamu Akasaki and published in 1995 by Baifukan K. K., first edition, Chapter 13). The p-type clad layer which is joined to this light-emitting layer has been heretofore usually formed of aluminum gallium nitride (Al_{X}Ga_{Y}N: 0≦X, Y≦1, X+Y=1) which possesses a comparatively large band gap at room temperature (refer, for example, to “Group III-V Compound Semiconductors” already cited).

A technique of depositing a p-type Group III nitride semiconductor layer intended to provide a positive (+) polar ohmic electrode as a contact layer on the p-type clad layer formed of the aforementioned aluminum gallium nitride has been disclosed (refer, for example, to JP-A HEI 8-23124). An example of forming the contact layer as with gallium nitride (GaN) doped with magnesium (Mg) and possessing a band gap narrower than that of the Group III nitride semiconductor material forming the clad layer has been disclosed (refer, for example, to JP-A HEI 8-23124 already cited).

An example of the technique of forming the contact layer of boron phosphide (BP) has been also disclosed (refer, for example, to JP-A HEI 2-288388). Heretofore, a technique to fabricate a laser diode through depositing a p-type BP layer doped with Mg as a contact layer on a p-type AlGaBNP layer has been disclosed (refer, for example, to JP-A HEI 2-275682). Further, a technique for fabricating a light-emitting diode through depositing a contact layer of BP doped with Mg as a p-type impurity on a superlattice structure formed of an Al_{X}Ga_{Y}N layer has been known (refer, for example, to JP-A HEI 2-288388 already cited). Then, a technique for fabricating an LED by directly disposing an ohmic positive electrode on a multi-element AlGaBNP mixed crystal layer, such as, for example, p-type Al_{0.25}Ga_{0.25}B_{0.50}N_{0.50}P_{0.50} has been disclosed (refer, for example, JP-A HEI 2-288371).

The aluminum gallium nitride (Al_{X}Ga_{Y}N: 0≦X, Y≦1, X+Y=1), a wide band gap material heretofore used for formation of a clad layer, however, brings a problem of encountering difficulty in forming an electroconductive layer [a layer for passing a device operation current (the current to operate a light-emitting device) from the positive electrode to the light-emitting layer] showing sufficiently low resistance. Even GaN which is utilized for forming a contact layer has not fully matured into a material suitable for a p-type electroconductive layer of low resistance. Thus, the acquisition of a light-emitting device of high emission has been obstructed by the fact that the device operation current allows no fully satisfactory planar diffusion in the light-emitting layer.

The conventional boron phosphide (BP) layer has a band gap of 2 eV (refer, for example, to JP-A HEI 2-275682 already cited). It, therefore, has not ability to penetrate the emission in the blue or green color band is allowed permeation. An effort to adopt the conventional BP layer of a narrow band gap as a contact layer and dispose it so as to direct the emission toward the exterior results in merely the absorption of emission and inconveniencing the acquisition of a light-emitting device of high luminance.

This invention has been initiated with a view to overcoming the problems encountered by the prior art as described above, and is aimed at providing a p-n junction-type compound semiconductor light-emitting diode which is capable of lowering the resistance of an electroconductive layer, enhancing the diffusion of the device drive current in a light-emitting layer, and endowing the electroconductive layer with transparency enough for passing the emission from the light-emitting layer to the exterior, thereby enabling the luminance of the diode to be enhanced.

### DISCLOSURE OF THE INVENTION

To accomplish the object described above, the first aspect of this invention provides a p-n junction-type compound semiconductor light-emitting diode provided on a crystal substrate with at least an n-type active (light-emitting) layer formed of a Group III nitride semiconductor as a light emitting layer, and with a Group III nitride semiconductor layer containing a p-type impurity on the n-type active layer, which diode has a boron phosphide-based Group III-V compound semiconductor layer possessing a band gap over that of the Group III nitride semiconductor forming the n-type active layer at room temperature and exhibiting a p-type electroconductivity in an undoped state deposited on the p-type impurity-containing Group III nitride semiconductor layer, and has an ohmic positive electrode joined to a surface of the boron phosphide-based Group III-V compound semiconductor layer.

The second aspect of this invention provides the p-n junction-type compound semiconductor light-emitting diode according to the first aspect, wherein the p-type impurity-containing Group III nitride semiconductor layer is a layer formed of a hexagonal wurtzite crystal type aluminum gallium nitride (Al_{X}Ga_{Y}N: 0≦X, Y≦1, X+Y=1), and wherein the boron phosphide-based Group III-V compound semiconductor layer is formed by stacking of (111) crystal face on a (0001) surface of the p-type impurity-containing Group III nitride semiconductor layer.

The third aspect of this invention provides the p-n junction-type compound semiconductor light-emitting diode according to the first aspect, wherein the p-type impurity-containing Group III nitride semiconductor layer is a layer formed of a hexagonal wurtzite crystal type gallium nitride, and wherein the boron phosphide-based Group Ill-V compound semiconductor layer is formed by stacking of (111) crystal face on a (0001) surface of the p-type impurity-containing Group III nitride semiconductor layer with a lattice spacing of roughly ½ of a c-axis lattice constant of the p-type impurity-containing Group III nitride semiconductor layer.

The fourth aspect of this invention provides the p-n junction-type compound semiconductor light-emitting diode according to any one of the first to third aspects, wherein the boron phosphide-based Group III-V compound semiconductor layer is formed of a crystal layer consisting of monomeric boron phosphide having a band gap of 2.8 electron bolts (eV) or more and 5.0 eV or less at room temperature, and has a component element number of 3 or less.

The fifth aspect of this invention provides the p-n junction-type compound semiconductor light-emitting diode according to any one of the first to fourth aspects, wherein the boron phosphide-based Group III-V compound semiconductor layer is formed of monomeric boron phosphide having a residual carbon atomic concentration of 6×10¹⁸ cm³ or less.

According to the first aspect of this invention, a boron phosphide-based Group III-V compound semiconductor layer possessing a band gap exceeding that of a Group III nitride semiconductor forming an n-type active layer at room temperature is formed on a Group III nitride semiconductor layer containing a p-type impurity. Therefore, the first aspect of the invention is capable of suppressing the absorption of emission from a light-emitting layer by an electroconductive layer, acquiring an enhanced transparency to the emission, improving efficiency of the passage of the emission to the exterior and exalting the luminance of the diode.

Further, in the first aspect, the boron phosphide-based Group III-V compound semiconductor layer on the p-type impurity-containing Group III nitride semiconductor layer is formed of a layer showing a p-type electroconductivity in an undoped state. Therefore, the first aspect of the invention is capable of securing a high carrier concentration in the undoped state and lowering the electric resistance of the layer. As a result, it can form an ohmic electrode of a low contact resistance and realize a p-n junction-type compound semiconductor diode endowed with a low forward voltage and an excellent rectifying property at a reverse voltage.

According to the second aspect of this invention, an ohmic positive electrode is disposed on a boron phosphide-based semiconductor layer provided on the (0001) surface of a hexagonal wurtzite crystal type aluminum gallium nitride (Al_{X}Ga_{Y}N: 0≦X, Y≦1, and X+Y=1) layer with an excellent lattice matching property. Therefore, the second aspect of the invention is capable of affording a p-n junction-type compound semiconductor light-emitting diode having merely a low local breakdown voltage.

The third aspect of the invention provides the p-n junction-type compound semiconductor light-emitting diode according to the first aspect, wherein the ohmic positive electrode is disposed on the boron phosphide-based semiconductor layer formed of a (111)-crystal face stacked in parallel on the (0001)-GaN surface with a lattice spacing of roughly ½ of the c-axis lattice constant and excelling in the matching property of the spacing of crystal lattice planes. Therefore, the third aspect of the invention is capable of providing a p-n junction-type compound semiconductor light-emitting diode excelling in the breakdown voltage in the reverse direction.

According to the fourth aspect of this invention, an ohmic positive electrode is disposed on a boron phosphide-based semiconductor layer formed of monomeric boron phosphide (BP) having a band gap of 2.8 eV or more and 5.0 eV or less at room temperature and a component element number of 3 (3 elements) or less. Therefore, the fourth aspect of the invention is capable of contributing to the provision of a p-n junction-type compound semiconductor light-emitting diode making convenient the extraction of emission to the exterior and abounding in the intensity of emission.

According to the fifth aspect of the invention, a boron phosphide-based semiconductor layer is configured with monomeric boron phosphide (BP) having a carbon atomic concentration of 6×10¹⁸ cm³ or less. Therefore, the fifth aspect of the invention is capable of providing a contact layer that affords optical transparency proper for the extraction of emission to the exterior and an excellent ohmic contact property and, as a result, providing a p-n junction-type compound semiconductor light-emitting diode withy low forward voltage and high intensity of emission.

The above and other objects, characteristic features and advantages of the present invention will become apparent to those skilled in the art from the description to be given herein below with reference to the accompanying drawings.

### BRIEF DESCRIPTION OF THE DRAWINGS

FIG. 1 is a schematic diagram illustrating a profile of a p-n junction-type compound semiconductor diode of this invention.

FIG. 2 is a schematic diagram illustrating a stacked structure used for the configuration of an LED.

FIG. 3 is a schematic plan view of an LED.

### BEST MODE FOR CARRYING OUT THE INVENTION

Now, an embodiment of this invention will be described in detail below with reference to the drawing annexed hereto.

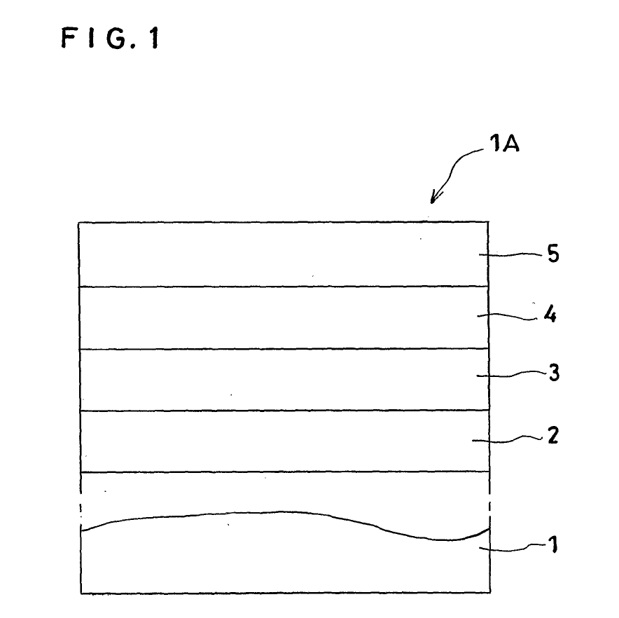

FIG. 1 is a schematic diagram depicting the sectional structure of a p-n junction-type compound semiconductor diode according to this invention. A p-n junction-type compound semiconductor diode 1A according to this invention, as illustrated in the diagram, is provided on a crystal substrate 1 at least with an n-type active (light-emitting) layer 2 and on the n-type active layer 2 with a Group III nitride type semiconductor layer 3 containing a p-type impurity, provided on the p-type impurity-containing Group III nitride semiconductor layer 3 with a boron phosphide-based Group III-V compound semiconductor layer 4 possessing a band gap exceeding the band gap of the Group III nitride semiconductor forming the n-type active layer 2 at room temperature and showing a p-type electroconductivity in an undoped state, and provided on the boron phosphide-based Group III-V compound semiconductor layer 4 as attached to the surface thereof with an ohmic positive electrode 5.

The boron phosphide-based Group III-V compound semiconductor (boron phosphide-based semiconductor layer) is a layer containing boron (B) and phosphorus (P) as essential component elements and is represented, for example, by B_{α}Al_{β}Ga_{δ}In_{1-α-β-δ}P_{1-δ}As_{δ} (0≦α≦1, 0≦β<1, 0≦δ<1, 0<α+β+δ≦1, 0≦δ<1). It is also represented, for example, by B_{α}Al_{β}Ga_{γ}In_{1-α-β-γ}P_{1-δ}N_{δ} (0<α≦1, 0≦β<1, 0≦δ<1, 0<α+β+γ≦1, 0≦δ<1). Among other compounds conceivable from the foregoing description, those compounds which have small numbers of component elements, such as, for example, monomeric boron phosphide (BP), boron gallium indium phosphide (B_{α}Ga_{γ}In_{1-α-γ}P; 0<α≦1, 0≦γ<1), are readily formed, and mixed crystals containing a plurality of Group V elements, such as boron phosphide nitride (BP_{1-δ}N_{δ:} 0≦δ<1) and boron phosphide arsenide (B_{α}P_{1-δ}As_{δ}), are usable particularly favorably for this invention.

The boron phosphide-based Group III-V compound semiconductor layers are formed by means of vapor growth, such as the halogen method, hydride method and the metal organic chemical vapor deposition (MOCVD) method. They can be formed by the molecular beam epitaxial method (refer, for example, to J. Solid State Chem., 133 (1997), pp. 269-272). For example, a p-type monomeric boron nitride (BP) layer can be formed by the atmospheric pressure (roughly atmospheric pressure) or reduced pressure MOCVD method using triethyl boron ((C₂H₅)₃B)) and phosphine (PH₃) as source materials. The temperature for forming the p-type BP layer is properly in the range of 1000° C. to 1200° C. The supply ratio of the source materials (V/III ratio=PH₃/(C₂H₅)₃B) during the course of formation is properly in the range of 10 to 50.

The boron phosphide-based Group III-V compound semiconductor layer is formed of a material of a wide band gap exceeding the band gap of the Group III nitride semiconductor material or the Group III-V compound semiconductor material forming the light-emitting layer. For the light-emitting layer formed of a Group III nitride semiconductor having a band gap of 2.7 electron volts (eV) at room temperature and emitting a blue color, a boron phosphide-based Group III-V compound semiconductor layer having a band gap in the range of 2.8 eV to 5.0 eV is used. When the difference of the band gap from the light-emitting layer is 0.1 eV or more, it is sufficient for the purpose of allowing the penetration of the emission from the light-emitting layer. The band gap can be determined by the dependency of the absorption coefficient on the photon energy (=hv). It can be otherwise determined by the photon energy dependency of the multiplied value (=2 nk) of refractive index (n) and the extinction coefficient (k).

By precisely controlling the rate of formation in addition to the formation temperature and the V/III ratio, it is made possible to form a boron phosphide-based Group III-V compound semiconductor layer having a wide band gap. In the formation of a layer of monomeric boron phosphide by the MOCVD method, for example, the boron phosphide layer having a band gap of 2.8 eV or more at room temperature can be obtained by setting the rate of formation (growth rate) in the range of 2 nm or more and 30 nm or less per minute. Particularly, the boron phosphide-based Group III-V compound semiconductor layer having a band gap of 2.8 eV or more and 5.0 eV or less at room temperature can favorably utilize even a window layer which is pervious to emission.

The boron phosphide-based semiconductor which is destitute of an ion bonding property readily produces a low resistance layer even in an undoped state, namely in a state not intentionally doping an impurity. From the monomeric boron phosphide (BP), for example, a p-type electroconductive layer having a carrier concentration exceeding 10¹⁹ cm⁻³ in an undoped state is readily obtained. That is, by using a boron-phosphide-based Group III-V compound semiconductor layer having a wide band gap, a contact layer which can form an ohmic electrode with only low contact resistance and, consequently, transmit emission to the exterior as well can be provided. Further, since the undoped boron phosphide-based layer inherently contains an impurity only in a small amount, the amount of an impurity diffused in the light-emitting layer is proportionately decreased. Thus, the problem owing to the diffusion of a p-type impurity, change in carrier concentration of light-emitting layer and consequently conduction type of the layer will be provided, and the discrepancy in forward voltage from what is expected (Vf) or in the emission of a wavelength from what is desired can be solved.

An ohmic electrode having a low contact resistance can be formed by disposing a p-type boron phosphide-based Group III-V compound semiconductor layer possessing a carrier concentration of 1×10¹⁹ cm⁻³ or more and a specific resistance of 5×10⁻² Ωcm or less at room temperature as a contact layer on a p-type clad layer formed of a p-type Group III nitride semiconductor. Thus, this fact is emphatically convenient with respect to the fabrication of a LED having a low forward voltage (Vf). The low-Vf LED, for example, is fabricated by utilizing an undoped p-type BP layer formed as a contact layer on a Mg-doped p-type Al_{X}Ga_{Y}N (0≦X, Y≦1, X+Y=1) clad layer. The thickness of the boron phosphide-based Group III-V compound semiconductor layer as the contact layer is properly 50 nm or more and 5000 nm or less.

The p-type boron phosphide-based Group III-V compound semiconductor layer according to this invention can be directly disposed as joined onto a light-emitting layer, such as Ga_{Y}In_{Z}N (0≦Y, Z≦1, Y+Z=1), which is generally grown at a comparatively low temperature. By forming a Group III nitride semiconductor layer formed at a higher temperature as a substrate layer on a light-emitting layer grown at a comparatively low temperature, it is made possible to form a boron phosphide-based Group III-V compound semiconductor layer excelling in crystallinity. Owing to the formation at the high temperature, the Group III nitride semiconductor layer of better crystallinity can be utilized as the substrate layer. Particularly, the use of the (0001) surface of the hexagonal wurtzite crystal type Al_{X}Ga_{Y}N (0≦X, Y≦1, X+Y=1) layer as a substrate layer brings the advantage of permitting formation of a (111) boron phosphide-based Group III-V compound semiconductor layer excelling in the matching property on the crystal lattice. The Al_{X}Ga_{Y}N layer containing a p-type impurity, such as Mg, which avoids occurrence of a crack in the doping of n-type impurities, such as silicon (Si), can be advantageously utilized as a substrate layer.

When Mg-doped gallium nitride (GaN) is used as a substrate layer, for example, a p-type boron phosphide-based Group III-V compound semiconductor layer provided on the (0001) surface thereof with a (111) crystal face matching in the direction and the lattice constant of the a-axis can be grown. That is, a p-type boron phosphide-based Group III-V compound semiconductor layer forming planar matching with the (0001) GaN crystal face can be formed. Further, a p-type (111) boron phosphide-based Group III-V compound semiconductor layer comprising a (111)-crystal face stacked in parallel to the (0001)-GaN surface with a spacing of roughly ½ of the c-axis lattice constant of the GaN. The p-type boron phosphide-based Group m-V compound semiconductor layer acquiring excellent matching also with the c-axis direction (vertical direction) and excelling in crystallinity can be formed. The relation between the spacing of lattice planes in the (111) crystal layer forming the boron phosphide-based Group III-V compound semiconductor layer and the c-axis of gallium nitride can be analyzed by utilizing, for example, electron beam diffraction, for example.

For the purpose of forming a (111) boron phosphide-based Group III-V compound semiconductor layer excelling in the ability to match the lattices to the c-axis on the (0001) surface of GaN, it is necessary that the temperature of growth and the rate of formation be controlled. The rate of formation is properly in the range of 20 nm to 30 nm per minute. The temperature of formation must be 750° C. or more and 1200° C. or less. If this temperature exceeds 1200° C., the overage will result in serious vaporization loss of the component elements, i.e. boron (B) and phosphorus (P), and consequent formation of stacking fault. Thus, the formation at the high temperature exceeding 1200° C. obstructs the formation of a boron phosphide-based Group III-V compound semiconductor layer comprising (111) crystal faces allowing a good matching to the c-axis of GaN.

The formation at a temperature below 1200° C. promotes the production of a boron phosphide-based Group III-V compound semiconductor layer having a low carbon (C) atomic concentration even with the MOCVD means using an organic boron compound. For example, a boron phosphide-based Group III-V compound semiconductor layer having a wide band gap, having a carbon atomic concentration of 6×10¹⁸ cm⁻³ or less, and permitting the passage of the emission in the blue light f a wavelength of 450 nm or the ultraviolet light of a wavelength of 380 nm at a transmission factor of 80% or more. Since the thermal decomposition of the organic boron compound proceeds prominently at a high temperature exceeding 1200° C., the amount of carbon incorporated into the layer is increased and the resultant boron phosphide-based Group III-V compound semiconductor layer exhibits a blackish color. The boron phoside-based Group III-V compound semiconductor layer without optical transparency is disadvantageous for the formation of a contact layer concurrently serving as a window layer.

This invention fabricates a compound semiconductor light-emitting device by disposing a p-type ohmic electrode (positive electrode) on a p-type low resistive boron phosphide-based Group III-V compound semiconductor layer. The p-type ohmic electrode may be formed of nickel (Ni) as a simple substance or an alloy thereof, gold (Au)-zinc (Zn) alloy or gold (Au)-beryllium (Be) alloy, for example. In the configuration of an ohmic electrode in a stacked structure, it is proper to form an uppermost layer of gold (Au) or aluminum (Al) for wire bonding.

In the case of an ohmic electrode in a three-layer stacked structure, for example, the intermediate layer which is interposed between the bottom and uppermost layer may be formed of a transition metal, such as titanium (Ti) or molybdenum (Mo) or platinum (Pt). In contrast, the n-type ohmic electrode (negative electrode) is formed on an n-type substrate or on an n-type layer formed on the substrate.

### EXAMPLE

This invention will be specifically described below by citing as an example the case of fabricating a p-n junction-type compound semiconductor LED utilizing a monomeric boron phosphide semiconductor layer formed on a p-type gallium nitride (GaN) layer.

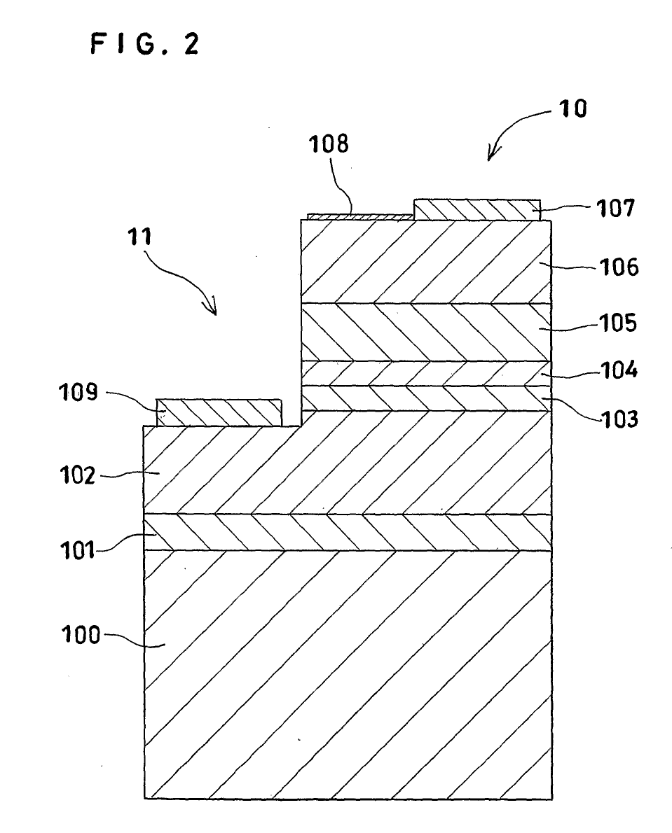

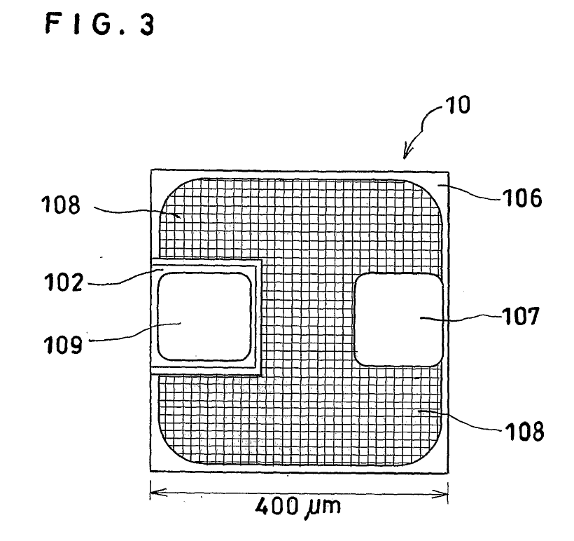

FIG. 2 schematically shows the cross-sectional view of a stacked structure 11 used for the fabrication of an LED 10 of a double hetero (DH) junction structure. FIG. 3 illustrates a schematic plan view of the LED 10.

The stacked structure 11 was formed by stacking on a (0001)-sapphire (α-Al₂O₃ single crystal) substrate 100, an undoped buffer layer 101 formed of GaN, a lower clad layer 102 formed of silicon (Si)-doped n-type GaN (n=7×10¹⁸ cm⁻³, layer thickness (t)=3 μm), a light-emitting layer 103 containing an undoped n-type Ga_{0.86}In_{0.14}N layer, an upper clad layer (Group III nitride semiconductor layer) 104 formed of Mg-doped p-type Al_{0.06}Ga_{0.94}N (p=3×10¹⁷ cm⁻³, t=0.08 μm), and a p-type layer (Group III nitride semiconductor layer) 105 formed of Mg-doped p-type GaN layer (p=7×10¹⁷ cm⁻³, t=0.1 μm) sequentially in the order mentioned. The individual layers 101 to 105 on the substrate 100 were invariably subjected to vapor growth by the ordinary reduced pressure MOCVD technique. The p-type Al_{0.06}Ga_{0.94}N layer 104 and the GaN layer 105 were formed at 1050° C.

The light-emitting layer 103 was in a multiple quantum well structure having an Si-doped n-type GaN layer (t=12 nm) as a barrier layer and a Ga_{0.86}In_{0.14} layer as a well layer. The light-emitting layer 103 was formed in a multiple quantum well structure with ive stacking periods involving the barrier layer contiguous to the n-type lower clad layer 102 and the well layer continuous to the p-type upper clad layer 104. The light-emitting layer 103 was formed at temperature of 750° C.

On the p-type GaN layer 105 which was formed at a higher temperature than in the case of the light-emitting layer 103, an undoped p-type boron phosphide (BP) layer (a boron phosphide-based Group III-V compound semiconductor layer) 106 was formed. The p-type monomeric boron phosphide layer 106 was formed utilizing the atmospheric pressure (roughly atmospheric pressure) metal organic chemical vapor deposition (MOCVD) technique that uses triethyl boron ((C₂H₅)₃B) as a boron (B) source and phosphine (PH₃) as a phosphorus source. The p-type boron phosphide layer 106 was formed at 1050° C. The V/III ratio (=PH₃/(C₂H₅)₃B concentration ratio) during the vapor growth of the p-type boron phosphide layer 106 was set at 15. The thickness of the p-type boron phosphide layer 106 formed at a rate of growth of 25 nm per minute was 0.35 μm.

The band gap at room temperature of the p-type boron phosphide layer 106 which was calculated by using the refractive index and the extinction coefficient determined by means of an ordinary spectrometric ellipsometer was about 4.3 eV. The acceptor concentration of the undoped p-type boron phosphide layer 106 determined by an ordinary electrolyte C-V (capacitance voltage) method was 2×10¹⁹ cm⁻³.

The stacking relation between the p-type GaN layer 105 and the p-type boron phosphide layer 106 was analized by examining image of selected-area electron diffraction (called “SAD”) taken by the use of an ordinary transmission electron microscope (abbreviated as “TEM”). In the SAD image, the diffraction spot regarding (0001) from the Mg-doped GaN layer 105 and the diffraction point regarding (111) from the p-type boron phosphide layer 106 appeared on a same straight line. This fact shows that the (111) crystal face of the p-type boron phosphide layer 106 was stacked on the (0001) surface of the Mg-doped GaN layer 105 in parallel to the crystal face thereof. The intervals (distances) at which the (0001) diffraction spots from the GaN layer 105 appeared on the same straight line in the SAD image were just twice the intervals (distances) at which the (111) diffraction points of the boron phosphide-based Group III-V compound semiconductor layer 106 appeared. This fact shows that the (111) crystal face of the boron phosphide layer 106 was stacked on the (0001) surface of the GaN layer 105 at a spacing of lattice planes of about ½ of the c-axis lattice constant of GaN.

When the interior of the p-type boron phosphide layer 106 was visually observed by cross-sectional TEM technique, the threading dislocation present in the lower p-type GaN layer 105 disappeared in the junction interface with the boron phosphide layer 106. Inside the p-type (111) boron phosphide layer 106, the presence of any misfit dislocation was not observed.

By the elemental analysis performed by an ordinary secondary ion mass spectroscopy (abbreviated as “SIMS”), the carbon (C) atom concentration in the interior of the undoped p-type boron phosphide layer 106 was 4×10¹⁷ cm⁻³. Thus, the p-type boron phosphide layer 105 acquired transparency high enough for passing the emission from the light-emitting layer.

The p-type boron phosphide layer 106 was provided on the first surface thereof with a p-type ohmic electrode 108 formed of a honeycomb type electrode consisting of a gold (Au) film and a nickel (Ni) oxide film produced by ordinary vacuum evaporation and electron beam evaporation (refer to FIG. 3). The p-type boron phosphide layer 106 was provided at one end thereof with a bonding pad electrode 107 made of a gold (Au) film and held in contact with the ohmic electrode 108. An n-type ohmic electrode 109 serving concurrently as a pad electrode was formed by the ordinary plasma etching technique on the surface of the n-type GaN layer 102 exposed by selective etching. Thereafter, the stacked structure 11 was sliced into LED chips 10 each measuring the square of 400 μm.

The device operation current of 20 mA was passed in the forward direction between the p-type and n-type ohmic electrodes 108 and 109 to examine emission property of the LED chip. The LED 10 emitted a blue band light having a central wavelength of 460 nm. By the determination using an ordinary integrating sphere, the chip prior to the resin molding was found to have a high output of emission of 5 mW. Owing to the disposition of the p-type ohmic electrode 108 on the boron phosphide layer 106 of low resistance, the forward voltage (Vf) was only 3.5 V. The reverse voltage exceeded 10 V when the reverse current was set at 10 μA. Thus, the LED 10 provided herein was found to excel in breakdown voltage in the reverse direction. Owing to the use of the p-type boron phosphide layer 106 which had no misfit dislocation, the LED 10 provided herein was free from local breakdown.

According to the present embodiment of this invention, the p-n junction-type compound semiconductor LED is fabricated by disposing an undoped p-type low-resistance boron phosphide-based Group III-V compound semiconductor layer possessing a band gap exceeding that of the Group III nitride semiconductor forming a light-emitting layer at room temperature on a p-type impurity-containing Group III nitride semiconductor layer and disposing an ohmic positive electrode on the layer as joined to the surface thereof. The p-n junction-type compound semiconductor light-emitting diode produced by this invention, therefore, acquires a low forward voltage and a high reverse voltage with good rectification property.

The present embodiment further contemplates disposing an ohmic positive electrode on a boron phosphide-based Group III-V compound semiconductor layer excelling in the lattice matching property and disposed on the (0001) surface of a hexagonal wurtzite crystal type aluminum gallium nitride (Al_{X}Ga_{Y}N: 0≦X, Y≦1, X+Y=1) layer and, as a result, can provide a p-n junction-type compound semiconductor light-emitting diode which entails no significant local breakdown.

This embodiment also contemplates disposing the ohmic positive electrode on the boron phosphide-based Group III-V compound semiconductor layer excelling in the matching property of the spacing of the crystal lattices formed of a (111)-crystal face stacked in parallel to the (0001)-GaN surface at a lattice spacing of about ½ of the c-axis lattice constant and excelling and, therefore, is capable of providing a p-n junction-type compound semiconductor light-emitting diode which excels in the blocking voltage in the reverse direction.

The embodiment contemplates disposing the ohmic positive electrode on a boron phosphide-based Group III-V compound semiconductor layer having a band gap of 2.8 eV or more and 5.0 eV or less at room temperature, using monomeric boron phosphide (BP) as a source material, and limiting a component element number below 3 (3 elements) and, therefore, is capable of making convenient the extraction of emission to the exterior and contributing to the provision of a p-n junction-type compound semiconductor light-emitting diode abounding in emission intensity.

The embodiment further contemplates configuring a boron phosphide-based Group III-V compound semiconductor layer with monomeric boron phosphide (BP) having a carbon atomic concentration of 6×10¹⁸ cm⁻³ or less and as a result is capable of providing a contact layer showing optical transparency proper for the extraction of emission to the exterior and satisfactory ohmic contact property and is consequently capable of providing a p-n junction-type compound semiconductor light-emitting diode which enjoys low forward voltage and abounding in emission intensity.

### INDUSTRIAL APPLICABILITY

In the present invention, the p-n junction-type compound semiconductor LED is configured, in which an undoped p-type low-resistive boron phosphide-based Group III-V compound semiconductor layer possessing a band gap exceeding that of the Group III nitride semiconductor forming a light-emitting layer at room temperature is disposed on a p-type impurity-containing Group III nitride semiconductor layer, and an ohmic positive electrode is disposed on the layer as joined to the surface thereof. The p-n junction-type compound semiconductor light-emitting diode produced by this invention, therefore, acquires a low forward voltage and a high reverse voltage with good rectification property.

1. A p-n junction-type compound semiconductor light-emitting diode provided on a crystal substrate with at least an n-type active layer formed of a Group III nitride semiconductor as a light emitting layer and on the n-type active layer with a Group III nitride semiconductor layer containing a p-type impurity, which diode has a boron phosphide-based Group III-V compound semiconductor layer possessing a band gap exceeding that of the Group III nitride semiconductor forming the n-type active layer at room temperature and exhibiting a p-type electroconductivity in an undoped state deposited on the p-type impurity-containing Group III nitride semiconductor layer, and has an ohmic positive electrode joined to a surface of the boron phosphide-based Group III-V compound semiconductor layer.

2. A p-n junction-type compound semiconductor tight-emitting diode according to claim 1, wherein the p-type impurity-containing Group III nitride semiconductor layer is a layer formed of a hexagonal wurtzite crystal type aluminum gallium nitride (AlₓGa_{y}N: 0≦X, Y≦1, X+Y=1) and wherein the boron phosphide-based Group III-V compound semiconductor layer is formed by stacking of a (111) crystal face on a (0001) surface of the p-type impurity-containing Group III nitride semiconductor layer.

3. A p-n junction-type compound semiconductor light-emitting diode according to claim 1, wherein the p-type impurity-containing Group III nitride semiconductor layer is a layer formed of a hexagonal wurtzite crystal type gallium nitride and wherein the boron phosphide-based Group III-V compound semiconductor layer is formed by stacking of a (111) crystal face on a (0001) surface of the p-type impurity-containing Group III nitride semiconductor layer with a lattice spacing of roughly ½ of a c-axis lattice constant of the p-type impurity-containing Group III nitride semiconductor layer.

4. A p-n junction-type compound semiconductor light-emitting diode according to claim 1, wherein the boron phosphide-based Group III-V compound semiconductor layer is formed of a crystal layer consisting of monomeric boron phosphide having a band gap of 2.8 electron volts (eV) or more and 5.0 eV or less at room temperature and having a component element number of 3 or less.

5. A p-n junction-type compound semiconductor light-emitting diode according to claim 1, wherein the boron phosphide-based Group III-V compound semiconductor layer is formed of monomeric boron phosphide having a residual carbon atomic concentration of 6×10¹⁸ cm⁻³ or less.
